(19) United States
(12) Patent Application Publication
(10) Pub. No.: US 2009/0159254 A1
(43) Pub. Date: Jun. 25, 2009

(54) HEAT SINK ASSEMBLY AND METHOD OF FABRICATING

(75) Inventors: Stephen Damian DELPRETE, Rehoboth, MA (US); Victor Horst KHEIL, Kitchener (CA); William PETROCELLI, Douglas, MA (US); Shiraz SAMEJA, South Attleboro, MA (US)

Correspondence Address: TYCO TECHNOLOGY RESOURCES, 4550 NEW LINDEN HILL ROAD, SUITE 140, WILMINGTON, DE, 19808-2952, US

(73) Assignee: TYCO Electronics Corporation, Middletown, PA (US)

(21) Appl. No.: 11/959,639

(22) Filed: Dec. 19, 2007

(51) Int. Cl. F28F 1/28; B23P 11/00; H05K 7/20

(52) U.S. Cl. 165/185; 29/428; 361/703

(57) ABSTRACT

A heat sink assembly and a method of fabricating a heat sink assembly. The heat sink assembly comprises a cylindrical core onto which are mounted a plurality of fin disks. The fin disks and cylindrical core are assembled to a threaded base. This assembly comprises the heat sink assembly. The heat sink assembly can be mounted onto a mounting clip or threaded directly onto a device having mating threads. The device can be a printed circuit board or components of a printed circuit board adapted to have threads or other electrical or electronic component that is adapted to have threads to receive the heat sink assembly. The fin disks are interference fit onto the cylindrical core to form a fin disk assembly to provide thermo-mechanical contact between the fin disks and the cylindrical core. The base is then interference fit onto the fin disk assembly to provide thermo-mechanical contact between the fin disk assembly and the base to form a heat sink assembly. The device can then be assembled to the electrical or electronic component requiring cooling.

### FIELD OF THE INVENTION

The present invention is generally directed to heat sinks for dissipating heat from heat producing devices, and more specifically to modular apparatus for dissipating heat generated by electronic solid state devices.

### BACKGROUND OF THE INVENTION

Heat sinks are utilized for efficient removal of heat from solid state devices such as microprocessors and printed circuit boards (PCB) that can be populated with micro-electro-mechanical systems (MEMS). Such electronic devices generate considerable heat during operation, and failure to effectively remove this heat can result in failure of the devices.

These heat sinks are currently provided in various sizes that are selected based on the heat generated by the device. The heat sinks comprise one or more fins integrally formed with and extending from a core having a threaded base that is threaded into an adaptor that is assembled to the device so that the heat sink is thermally coupled to the device. The core conducts the heat away from the electronic device, and the fins integrally assembled to the core conduct heat away from the core, thereby keeping the device at an acceptable temperature. Of course, it would be a simple matter to overdesign heat sinks and provide a single size. However, aside from cost considerations, space restrictions usually limit the height of the core or the diameter of the fins, even when the heat dissipation requirements for two different applications are substantially the same, thereby requiring heat sinks having different configurations.

The heat sinks are formed by machining by machining from bar stock. Since the size of the heat sink will depend on the amount of heat that must be removed, it is necessary to manufacture heat sinks in different sizes in order to provide heat sinks for different applications. It is expensive and time consuming to machine these heat sinks, and it is expensive to maintain an inventory of heat sinks of different sizes for different applications.

It would be desirable to provide heat sinks that are assembled using a modular design that implements a plurality of interchangeable parts that can be used to provide heat sinks having different heat dissipation capabilities. If the machining of the interchangeable parts can be minimized, the cost of manufacturing the heat sinks can be significantly reduced. Similarly the cost of maintaining inventories of heat sinks of different sizes can be reduced.

### SUMMARY OF THE INVENTION

The present invention provides a heat sink assembly and a method of fabricating a heat sink assembly. The heat sink assembly comprises a cylindrical core onto which are mounted a plurality of fin disks. The fin disks and cylindrical core are assembled to a threaded base. This assembly comprises the heat sink assembly. The heat sink assembly can be mounted onto a mounting clip or threaded directly onto a device having mating threads. The device can be a printed circuit board adapted to have threads or other electrical or electronic component that is adapted to have threads to receive the heat sink assembly.

The assembly is fabricated by providing a plurality of fin disks each having an aperture with a predetermined internal diameter. The plurality of fin disks are assembled over an alignment post on a fin disk assembly tool, the alignment post having an outer diameter that is larger than the internal diameter of the aperture on the fin disks. The cylindrical core, which is a pipe having an outer diameter that is sized to have an interference fit with the predetermined internal diameter of the fin disk apertures, that is, pipe outer diameter is slightly larger than the fin disk aperture internal diameters, and an inner diameter that is slightly larger than the outer diameter of the alignment post, is placed over the alignment post of the fin disk assembly tool. While on the fin disk assembly tool, the cylindrical pipe core is then press fit to the fin disks through the fin disk apertures to form a pipe core assembly. A threaded base having a first end with a projection and a second end with a threaded base is then placed onto a base insertion press that secures the base in position. The projection has a preselected size that allows it to be interference fit with the pipe. The pipe core assembly is secured in position and placed under the base insert press so that the projection end of the threaded base is press fit onto the pipe core assembly, forming the heat sink assembly, while leaving the threads in the threaded base exposed for additional assembly.

The heat sink assembly can then be assembled to well-known mounting clips. Alternatively, PCBs can be provided that include mating threads that permit the heat sink assemblies to be mounted directly to the PCBs. PCBs include motherboards to which are mounted VGA chips. Such chips draw a much as 5-15 watts of power, a large portion of which is dissipated by heat. Other electrical or electronic components can be provided with threads to permit direct mounting of the heat sink assemblies as well.

An advantage of the present invention is that the heat sinks are modular in design. Rather than having an inventory that involves machining of a large number of heat sinks, that is heat sinks having two, three, four or more fins, the heat sinks can be assembled in a modular fashion that eliminates most machining. The fin disks can be stamped and then assembled with the number of fins desired. Pipe cores can be provided in sizes required to accommodate a required number of fin disks that are assembled onto the pipe cores. The threaded bases can be provided in one or more standard thread sizes.

Another advantage is that modular heat sinks of the present invention, even though having different heat dissipation capacity, can utilize common components. These common components can be provided without the expense of custom machining, allowing for heat sink assemblies that are less expensive to fabricate while providing the same heat dissipation capability as current machined heat sinks.

Still another advantage is that heat sink assembly components can be made by processed such as stamping and maintained in inventory until ready for assembly. Only the threading operation requires machining.

Another advantage of the present invention is that the equipment required for assembling the heat sink assemblies is relatively inexpensive. This equipment can be used to provide heat sink assemblies over the entire range of fin disks required.

Finally, an inventory of modular heat sink assemblies can be maintained at a lower cost than machined heat sinks.

Other features and advantages of the present invention will be apparent from the following more detailed description of the preferred embodiment, taken in conjunction with the accompanying drawings which illustrate, by way of example, the principles of the invention.

### BRIEF DESCRIPTION OF THE DRAWINGS

FIG. 1 is a side view of the heat sink assembly of the present invention.

FIG. 2 is an exploded view of the heat sink assembly of the present invention.

FIG. 3 is a perspective view of the fin disks of the present invention.

FIG. 4 is a perspective view of the cylinder core of the present invention.

FIG. 5 is a perspective view of the threaded base of the present invention.

FIG. 6 depicts four fin disks 30 assembled with flange 38 facing downward onto a fin disk assembly fixture having a center shaft.

FIG. 7 depicts a core being assembled over the center shaft of the fin disk assembly fixture of the fin disk of FIG. 6.

FIG. 8 depicts a fin disk assembly and base being assembled onto a base insertion press tool.

FIG. 9 depicts an exploded view of a heat sink assembly of the present invention and a mating mounting clip 50.

### DETAILED DESCRIPTION OF THE INVENTION

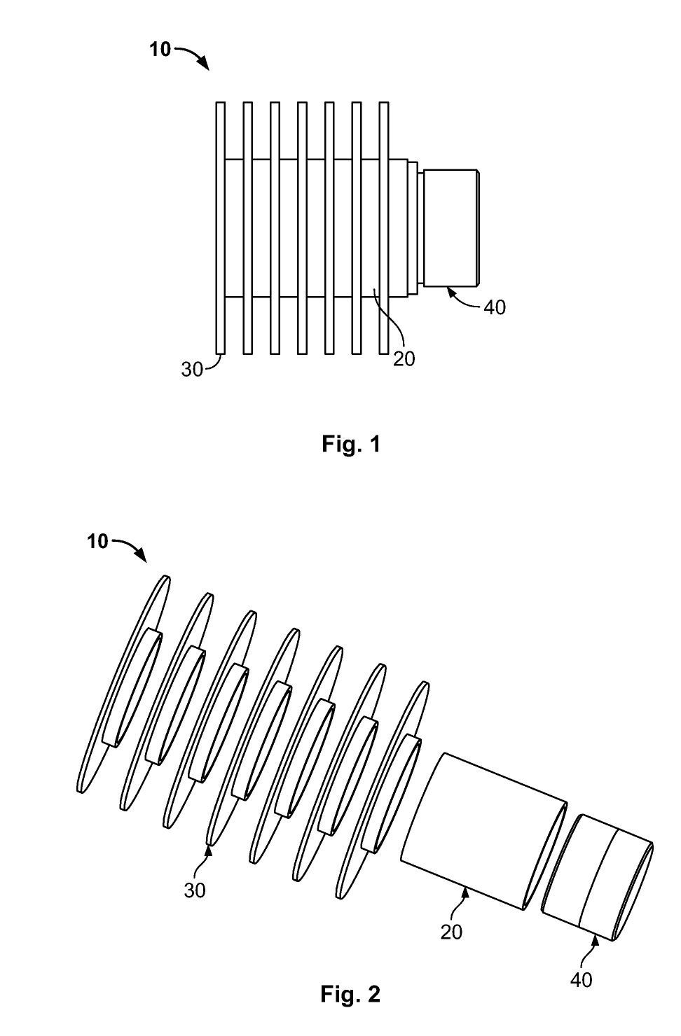

FIG. 1 depicts a heat sink assembly 10 of the present invention. Heat sink assembly 10 comprises a cylindrical core 20 onto which are mounted a plurality of fin disks 30. The fin disks 30 and cylindrical core 20 are assembled to a threaded base 40. FIG. 2 is an exploded view of the heat sink assembly of FIG. 1.

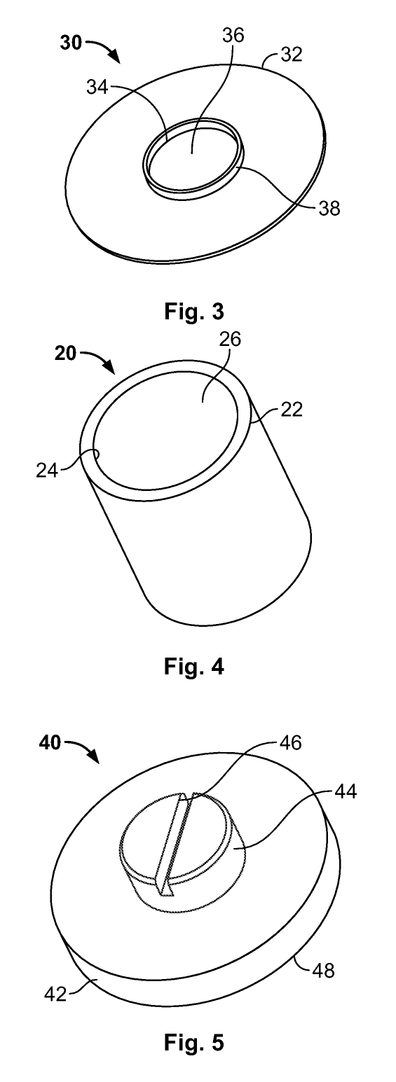

FIG. 3 depicts a fin disk 30 used in the current invention. Each fin disk 30 includes an axis or centerline that is the basis for an outer diameter 32 and an inner diameter 34 and a disk-shaped section between the inner and outer diameter. The inner diameter 34 defines a central aperture or bore 36. Immediately adjacent the inner diameter is a flange 38 that is substantially perpendicular to the fin disk axis. The inner diameter 34 is of a first predetermined size. The outer diameter 32 is of a second preselected size. The size of the outer diameter 32 is selected based on the required heat dissipation requirements for the heat sink assembly. Thus, if additional heat dissipation is required of an assembly, increasing the heat dissipation of a fin disk can be accomplished by increasing the outer diameter size while holding the size of the inner diameter 34 constant. Thus, a plurality of disk fins 30 having different outer diameter sizes can be stamped and provided depending on the heat dissipation requirements of the heat sink assembly. Flange 38 is formed to separate the fin disks when they are assembled together. Preferably, fin disks 30 are stamped from aluminum or aluminum alloy, copper or copper alloy, although any other metals with high thermal conductivity that are malleable for ease of formability may be used. While stamping currently provides the most economic method of manufacturing the fin disks, the fin disks may be manufactured by other methods such as casting, including investment casting or injection molding.

FIG. 4 depicts a perspective view of core 20. As can be seen, core 20 in its preferred embodiment has the shape of a cylindrical pipe. This shape is selected as it is the most economical to form, and there is nothing to preclude a different geometric shape for this element. Fin disks 30 are interference-fit onto core 20, preferably by a press fit operation, and, as will be apparent, any aperture shape of the fin disk 30 that can match the outer surface shape of core 20 can be utilized. In a preferred embodiment, the core 20 includes an outer diameter 22 and an inner diameter 24, inner diameter 24 forming the basis for aperture 26. Outer diameter 22 is sized to be slightly larger than fin disk inner diameter 34 and fin disk aperture 36, allowing core 20 to be interference fit into one or more fin disks 30. Interference-fitting a plurality of fin disks 30 to core 20 also establishes surface-to-surface contact between the two parts. Preferably, cores 20 are manufactured from the same material as the fin disks 30. The size of the cores is determined by the number of fin disks that are assembled onto the core. However, since the number of fin disks 30 that can be assembled onto a core 20 is an integral number, and limited, only a discrete number of cores 20 of different sizes must be maintained. Thus, once the number of fin disks 30 required to provide heat dissipation for an application is determined, a core of the proper size is selected for assembly. Thus core diameters 22, 24 can be maintained for a series of heat sink applications, while only the length is discretely varied.

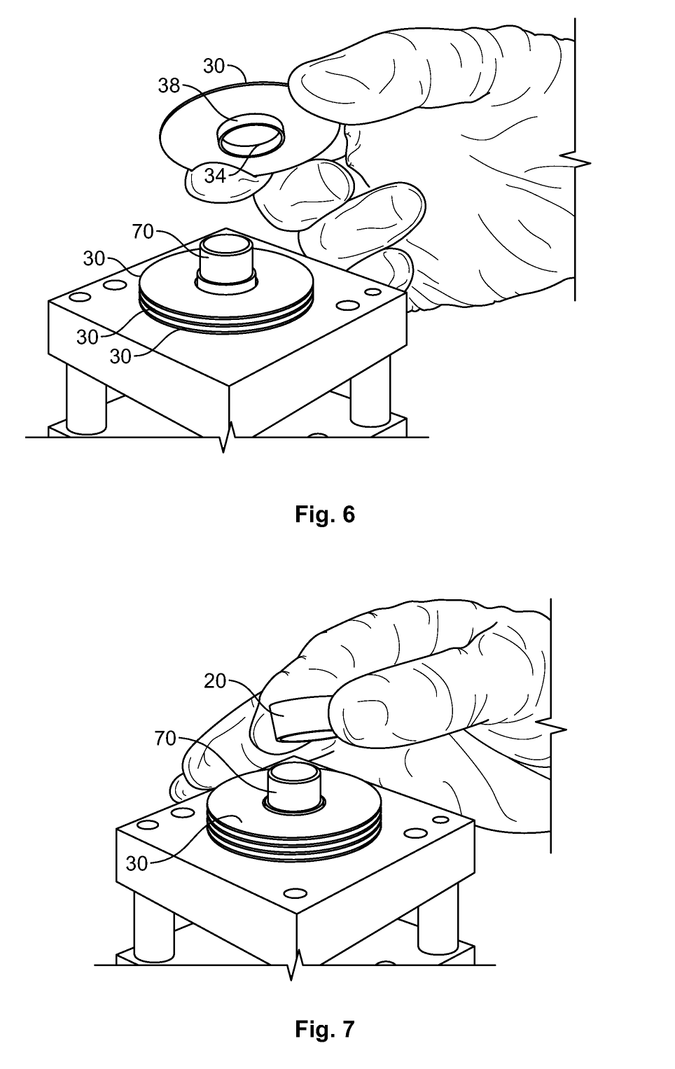

FIG. 5 depicts threaded base 40 of heat sink assembly 10. In one embodiment, base 40 has an outer diameter 42, which is threaded. Outer diameter 42 has a preselected size. The outer diameter 42 is threaded, and the size of the outer diameter is determined by the thread size required. Various applications require different thread sizes. Preferred thread sizes currently vary from ⅝″ to 1½″ but these preferred thread sizes are not limiting as additional thread sizes can be designed and utilized. Threaded base also includes a post 44. Post 44 also includes a tool feature 46. Post 44 extends away from a body portion of the base that includes outer diameter 42. The diameter of post 44 is dimensioned to be slightly larger than core inner diameter 24, so that the core can be interference fit onto the base 40. The bottom 48 of base 40, which is in contact with the hot component, a PCB, MEMS or other electronic component, is opposite post 44 and is very flat, so that base 40 can establish intimate thermal contact with the part requiring cooling, thereby drawing heat from the part. While the threads on outer diameter of base 42 are machined using conventional practice, the base is otherwise formed from a material having excellent thermal conductivity, usually the same material as the core and the fin disks and can be formed by a stamping operation. Tool feature 46 is provided so that a tool can be inserted into heat sink assembly 10, and engage tool feature 46 to torque the threads of base 40 heat sink assembly 10 into mating threads on the receiving part. In the preferred embodiment of FIG. 5, this tool feature 46 is a slot for a screwdriver, but may be an Allen wrench slot, a Torx aperture, a Phillips aperture, a hex opening or any other suitable tool feature 46 to receive a tool and permit torquing of the heat sink assembly 10.

The heat sink assembly of the present invention can then be threaded into mating threads. The mating threads can be in a solid state device in which the heat sink bottoms against the device to provide intimate contact to provide thermal conduction away from the solid state device. Alternatively, the heat sink assembly can thread into adaptors identical to those currently in use that are mounted on electrical components to provide thermal conduction away from the solid state device to the heat sink assembly.

Still referring to FIG. 5, in another embodiment, outer diameter 42 of threaded base is not required to be threaded. Instead, after fabrication of the heat sink assembly 10, the bottom 48 of base 40 is provided with a thermally conductive adhesive material. This material is provided with a protective release layer. The heat sink assembly 10 is applied by removing the release layer and applying the thermally conductive adhesive directly to the component from which heat is to be transferred, thereby attaching the heat sink assembly 10 to the component. In this embodiment, the thermally conductive adhesive material serves as the attachment mechanism to the component that requires cooling.

The production of the heat sink assembly 10 of the present invention is accomplished by mechanical assembly. While the prior art heat sinks are machined from a single piece of material, the heat sinks of the present invention are somewhat different. Since the heat sink assemblies of the present invention comprise a number of different parts, the effectiveness of these assemblies is highly dependent on establishing good mechanical interfaces between these parts so that heat can be conducted across these interfaces. Failure to establish good mechanical interfaces could result in small air gaps, which actually have an insulative effect, resulting in exactly an opposite result from that desired. The desired mechanical interfaces are established by interference fits between the mating parts. While any method of establishing reliable mechanical interfaces between the mating parts is acceptable, such as, for example, shrink fitting of parts, which involves using the differential thermal expansion properties of materials when assembling different parts at different temperatures during assembly, a preferred method is press fitting.

FIGS. 6-9 demonstrate one way for fabricating the heat sink assemblies of the present invention by press fitting. In FIG. 6, a preselected number of fin disks 30, four in FIG. 6, are assembled, flange 38 facing downward onto a fin disk assembly fixture having a center shaft 70, the shaft diameter being slightly smaller than the core inner diameter 24. Flange 38 maintains the spacing between adjacent fin disks 30. FIG. 7 depicts a cylindrical core 20, having a size selected to match the number of fin disks, being assembled over the center shaft of the fin disk assembly fixture. A press having a platen is brought to bear against the assembled fin disks 30, urging the core into the slightly smaller fin disk aperture to establish contact between the fin disks and the core outer diameter, forming a fin disk assembly.

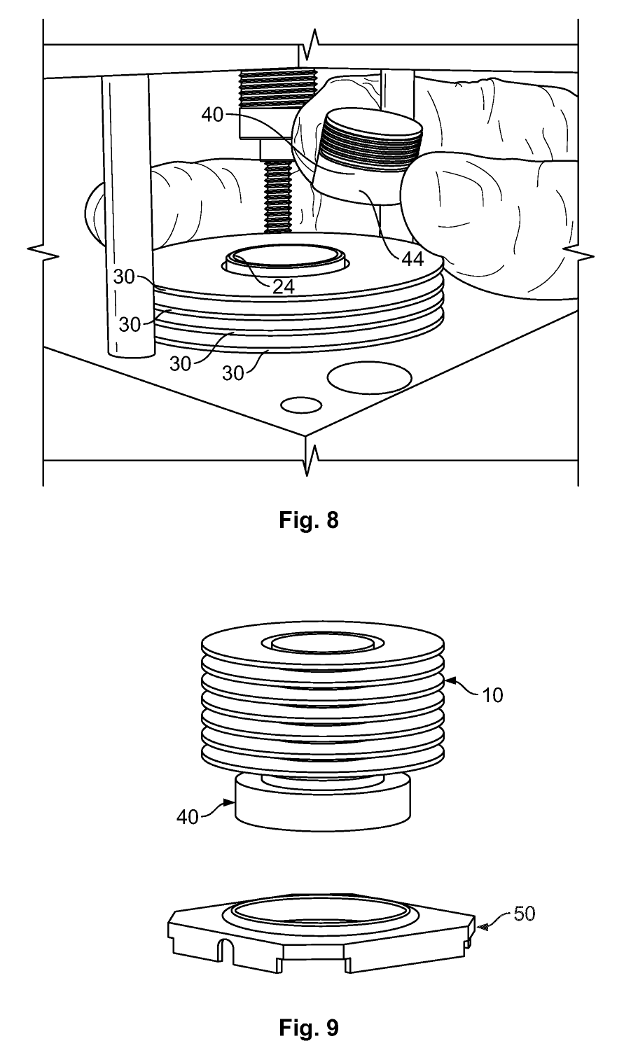

FIG. 8 depicts a fin disk assembly being assembled onto a base insertion press tool. The fin disk assembly is flipped over so that the flange side is facing upward, that is, at 180° from FIG. 6. The fin disk assembly is secured on the press lower platen to prevent movement by any convenient means, such as by three position posts duplicating the diameter of the fin disk assembly. Next, as depicted in FIG. 9, a threaded base 40 is assembled onto a tool on the press upper platen with the tool feature and centered in position over the fin disk assembly. The threaded base is then pressed into position into the cylindrical core 20, the inner diameter 24 of cylindrical core 20 being slightly smaller than the diameter of post portion of threaded base 40, to form a heat sink assembly 10.

Effective interference fits can be established between mating parts whose inner and outer dimensions differ by as little as a few tenths (of a mil), where one tenth is 0.0001 inches, to as much as 0.007 inches where 0.001 inches is a mil. The specific method to establish an interference fit between mating assemblies is not important.

After the heat sink assembly is formed from its component parts, the heat sink assembly can be matched with corresponding threads, here female threads and assembled onto an electronic component requiring cooling. Tool feature 46 is accessed through core aperture 26 with the appropriate tool so that heat sink assembly 10 can be properly torqued into place. The torque range for the most commonly used heat sink assemblies 10 is from about 1-in-lbs, the specified torque depending upon the actual size of the heat sing assembly package.

One embodiment, depicted in FIG. 9, is an exploded view of a heat sink assembly of the present invention and a mating mounting clip 50. Mounting clip 50 includes threads that mate with threaded base 40 of heat sink assembly 10. Typically, mounting clips 50 usually are of non-conductive materials and snap onto devices, referred to as ball grit (BGA) array packages soldered onto PCBs and motherboards, which are designed to accept the mounting clips. When the heat sink assembly 10 of the present invention is properly torqued to mounting clip 50 and mounting clip 50 is properly assembly to a PCB or a motherboard, a conductive path is directly established between the heat sink assembly 10 and the electronic components to remove heat from the electronic components.

While the invention has been described with reference to a preferred embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. A heat sink assembly, comprising:
a plurality of fin disks, each fin disk having an outer dimension of preselected size, an inner dimension having a preselected size forming an aperture, and a flange extending substantially perpendicular to the aperture;
a core having an inner dimension of preselected size forming a core aperture, and an outer dimension having a size greater than the inner dimension of the fin disk, so that the outer dimension of the core can form an interference fit with the inner dimension of each fin disk, and having an axial length of preselected size; and
a base having a top surface, a bottom surface and an outer diameter of preselected size extending between the top and bottom surface and a post extending axially away from the top surface, the post being dimensioned from an interference fit within the aperture of the core.

2. The heat sink assembly of claim 1 wherein the base post includes a top surface, and the top surface includes a tool feature.

3. The heat sink assembly of claim 2 wherein the tool feature is a slot dimensioned to receive a screwdriver.

4. The heat sink assembly of claim 1 wherein each fin disk includes a flange, the flange providing substantially uniform spacing between fin disks when the fin disks are interference fit onto the outer diameter of the core.

5. The heat sink assembly of claim 1 wherein the inner dimension of the core is a diameter, and the post has a diameter that is greater than the diameter of the core.

6. The heat sink assembly of claim 5 wherein the post diameter is sized about 0.0001 inches greater than the inner diameter of the core.

7. The heat sink assembly of claim 1 wherein the outer dimension of the core is a diameter and the inner dimension of the fin disk is a diameter.

8. The heat sink assembly of claim 7 wherein the core outer diameter is sized about 0.0001 inches greater than the inner diameter of the fin disk diameter.

9. The heat sink assembly of claim 7 wherein the core is a cylinder having an inner diameter of preselected size forming a core aperture, and an outer diameter of preselected size, so that the core can form an interference fit with each fin disk.

10. The heat sink assembly of claim 1 wherein the preselected size of the axial length of the core is determined by a number of fin disks in the plurality of fin disks.

11. The heat sink assembly of claim 1 wherein the core, the base and the fin disks comprise a conductive metal.

12. The heat sink assembly of claim 11 wherein the core, the base and the fin disks are selected from the group of conductive metals consisting of aluminum and its alloys and copper and its alloys.

13. The heat sink assembly of claim 1 wherein the outer diameter of the base further includes threads.

14. The heat sink assembly of claim 1 wherein the bottom surface of the base further includes a thermally conductive adhesive.

15. A method of manufacturing a heat sink assembly, comprising:
providing a plurality of fin disks, each fin disk having an outer diameter of preselected size, an inner diameter having a preselected size forming an aperture, and a flange extending substantially perpendicular to the aperture;
providing a cylindrical core having an inner diameter of preselected size forming a core aperture, and an outer diameter having a size greater than the inner diameter of the fin disk inner diameter, so that the outer diameter of the core can form an interference fit with the inner diameter of each fin disk, and having an axial length of preselected size;
providing a base having a top surface, a bottom surface and an outer diameter of preselected size extending between the top and bottom surface, the outer diameter including threads, and a post extending axially away from the top surface, the post having a feature perpendicular to the axis sized greater than the inner diameter of the core, so that the post can form an interference fit with the inner diameter of the core;
fitting the cylindrical core to the plurality of fin disks by an interference fit to form a fin disk assembly; and
fitting the fin disk assembly to the base by an interference fit.

16. The method of manufacturing a heat sink assembly of claim 15 wherein the step of providing a plurality of fin disks includes providing a plurality of stamped fin disks.

17. The method of manufacturing a heat sink assembly of claim 15 wherein the step of providing a cylindrical core includes providing a pipe.

18. The step of manufacturing a heat sink assembly of claim 15 wherein at least one of the steps of fitting by an interference fit includes fitting by differential thermal expansion.

19. The step of manufacturing a heat sink assembly of claim 15 wherein at least one of the steps of fitting by an interference fit includes fitting by press fitting.

20. The step of manufacturing of claim 15 further including assembling the plurality of fin disks onto an assembly tool having a center shaft and pressing the cylindrical core over the center shaft and into the inner diameter of the fin disks to form a fin disk assembly with mechanical contact for thermal conduction between the fin disks and the cylindrical core.

21. The step of manufacturing of claim 20 further including assembling the fin disk assembly securely onto a machine press, assembling a base onto the machine press and pressing the base and the fin disk assembly together to form a heat sink assembly.

22. A heat sink system, comprising:
a heat sink assembly, which further comprises,
a plurality of fin disks, each fin disk having an outer dimension of preselected size, an inner dimension having a preselected size forming an aperture, and a flange extending substantially perpendicular to the aperture,
a core having an inner dimension of preselected size forming a core aperture, and an outer dimension having a size greater than the inner dimension of the fin disk, so that the outer dimension of the core can form an interference fit with the inner dimension of each fin disk, and having an axial length of preselected size, and
a base having a top surface, a bottom surface and an outer diameter of preselected size extending between the top and bottom surface, the outer diameter including threads, and a post extending axially away from the top surface, the post having a feature perpendicular to the axis sized greater than the inner dimension of the core, so that the post can form an interference fit with the inner dimension of the core; and
an electrical component in thermo-mechanical contact with the heat sink assembly to conduct heat away from the electrical component.
